(19) United States
(12) Patent Application Publication
(10) Pub. No.: US 2025/0015678 A1
(43) Pub. Date: Jan. 9, 2025

(54) CIRCUIT-INTEGRATED MOTOR

(71) Applicant: MIKUNI CORPORATION, Tokyo (JP)

(72) Inventors: Naoki TANAKA, Odawara-shi (JP); Yoshitaka KOGA, Odawara-shi (JP)

(21) Appl. No.: 18/656,701

(22) Filed: May 7, 2024

(30) Foreign Application Priority Data
Jul. 3, 2023 (JP) 2023-108998

(51) Int. Cl. H02K 11/33; H02K 5/22; H02K 9/22

(52) U.S. Cl. CPC H02K 11/33; H02K 5/225; H02K 9/227

(57) ABSTRACT

A circuit-integrated motor 100 (100A to 100D) includes: a motor 10; a control board 40 for controlling the motor 10; a casing 50 including a partition wall portion 60 made of metal and dividing a board housing chamber 51 for housing the control board 40 from a placement space for the motor 10; a terminal 70 for connecting the control board 40 to an external device; and a terminal holder 80 formed of resin and holding the terminal 70. The terminal holder 80 is molded integrally with the partition wall portion 60 by insert molding with the partition wall portion 60 and the terminal 70 being insert parts.

### TECHNICAL FIELD

The present disclosure relates to a circuit-integrated motor in which a motor and a control unit (control board) are integrated into a single module.

### BACKGROUND

Conventionally, a circuit-integrated motor has been known in which a motor and a control unit are integrated into a single module.

In the circuit-integrated motor, in general, the control board is housed in a board housing chamber separated from a motor placement space and the control board in the board housing chamber is connected to an external device via a connector.

For example, Patent Document 1 describes an electric motor assembly (circuit-integrated motor) in which a motor is integrated with a controller including a control circuit board and a power circuit board.

In the electric motor assembly described in Patent Document 1, the control circuit board is attached from a motor side to a heat sink fastened to a motor case, and the power circuit board is attached from a side opposite to the motor. The control circuit board and the power circuit board are covered by a cylindrical member surrounding the heat sink and formed of resin and a cover attached to the cylindrical member. The cylindrical member formed of the resin is integrally provided with various connectors (a power connector, a signal connector, and a torque signal connector) for connecting the control circuit board and the power circuit board to the external device.

As another example of the circuit-integrated motor, Patent Document 2 describes a drive device in which a control board is disposed above a motor housing and a motor wire protruding from the motor housing is connected to the control board.

In the drive device described in Patent Document 2, an annular connector surrounding the control board and formed of resin is attached to the motor housing via an adhesive. The connector formed of the resin is provided with various pins (a sensor pin, a communication pin, and a power pin) for connecting the control board to an external device.

### CITATION LIST

### Patent Literature

Patent Document 1: JP2012-143036A
Patent Document 2: JP7211259B

### SUMMARY

A circuit-integrated motor is generally assembled with numerous parts including a partition wall for separating a board housing chamber where a control board is housed from a motor placement space and a connector for connecting the control board to an external device.

For example, when a connector including a terminal and a terminal holder formed of resin is fastened to the partition wall with a screw, etc., in addition to a fastening component such as the screw, a seal member for maintaining sealability of the board housing chamber is also required, increasing the number of parts. Further, from the viewpoint of reducing a production cost of the circuit-integrated motor, assembly man-hours for these numerous parts can also be a problem.

Also in the electric motor assembly described in Patent Document 1 and the drive device described in Patent Document 2, the connector (the cylindrical member formed of the resin in Patent Document 1; the connector formed of the resin in Patent Document 2) including the terminal and the terminal holder formed of the resin and the partition wall dividing the board housing chamber from the motor placement space are configured separately.

In view of the above, an object of at least some embodiments of the present invention is to provide a circuit-integrated motor capable of reducing the number of parts and part assembly man-hours.

A circuit-integrated motor according to at least some embodiments of the present invention, includes: a motor; a control board for controlling the motor; a casing including a partition wall portion made of metal and dividing a board housing chamber for housing the control board from a placement space for the motor; a terminal for connecting the control board to an external device; and a terminal holder formed of resin and holding the terminal. The terminal holder is molded integrally with the partition wall portion by insert molding with the partition wall portion and the terminal being insert parts.

According to at least some embodiments of the present invention, since the terminal holder is disposed integrally with the terminal and the partition wall portion for dividing the board housing chamber from the motor placement space, the number of parts and part assembly man-hours can be reduced compared to a case where a connector including the terminal and the terminal holder formed of the resin is fastened to the partition wall portion.

### BRIEF DESCRIPTION OF DRAWINGS

FIG. 1 is a cross-sectional view schematically showing a circuit-integrated motor according to an embodiment.

FIG. 2 is a cross-sectional view schematically showing a circuit-integrated motor according to an embodiment.

FIG. 3 is a perspective view showing an overall configuration of a circuit-integrated motor according to an embodiment.

FIG. 4 is a perspective view showing a state of the circuit-integrated motor before a cover is attached according to an embodiment.

FIG. 5 is a perspective view illustrating, of an insert molded article of the circuit-integrated motor, a partition wall portion separately from other portions according to an embodiment.

FIG. 6 is a perspective view showing an overall configuration of a circuit-integrated motor according to an embodiment.

FIG. 7 is a perspective view showing a state of the circuit-integrated motor before the cover is attached according to an embodiment.

FIG. 8 is a perspective view illustrating, of an insert molded article of the circuit-integrated motor, the partition wall portion separately from the other portions according to an embodiment.

### DETAILED DESCRIPTION

Some embodiments of the present invention will be described below with reference to the accompanying drawings. It is intended, however, that unless particularly identified, dimensions, materials, shapes, relative positions and the like of components described or shown in the drawings as the embodiments shall be interpreted as illustrative only and not intended to limit the scope of the present invention.

Hereinafter, a circuit-integrated motor according to some embodiments will be described with reference to the accompanying drawings. The circuit-integrated motor described below is a motor and control unit (control board) integrated into a single module, and may be, for example, a motor device for driving a radiator fan or an in-car motor device such as a motor for driving a vacuum pump.

Unless otherwise specified, the “axial direction”, “radial direction”, and “circumferential direction” in the specification refer to the axial direction, radial direction, and circumferential direction of the circuit-integrated motor, respectively.

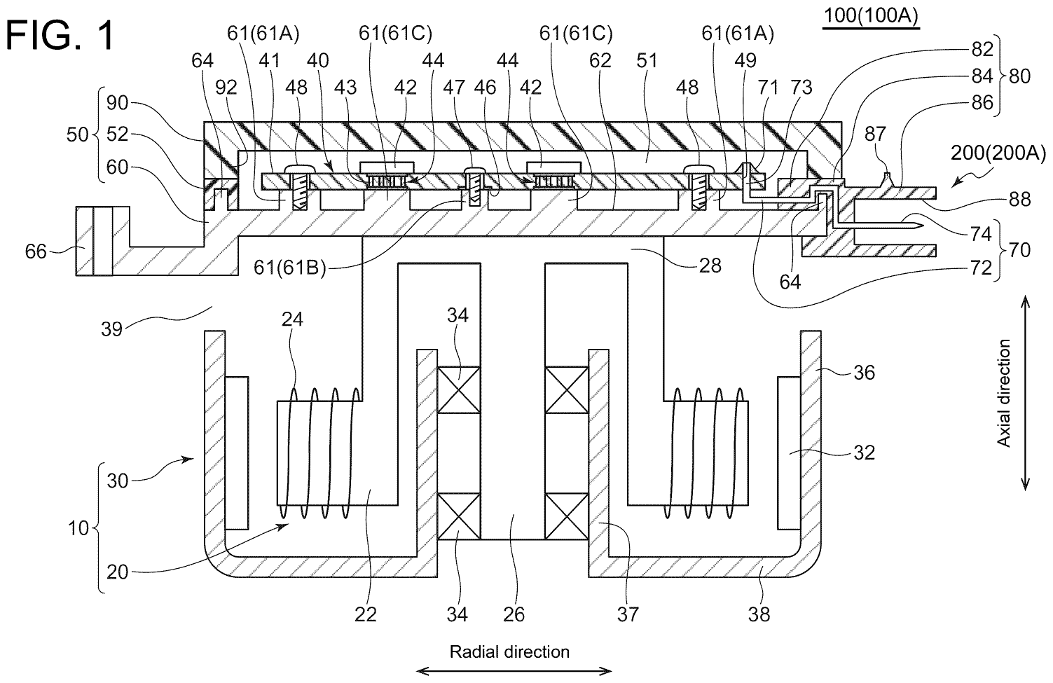

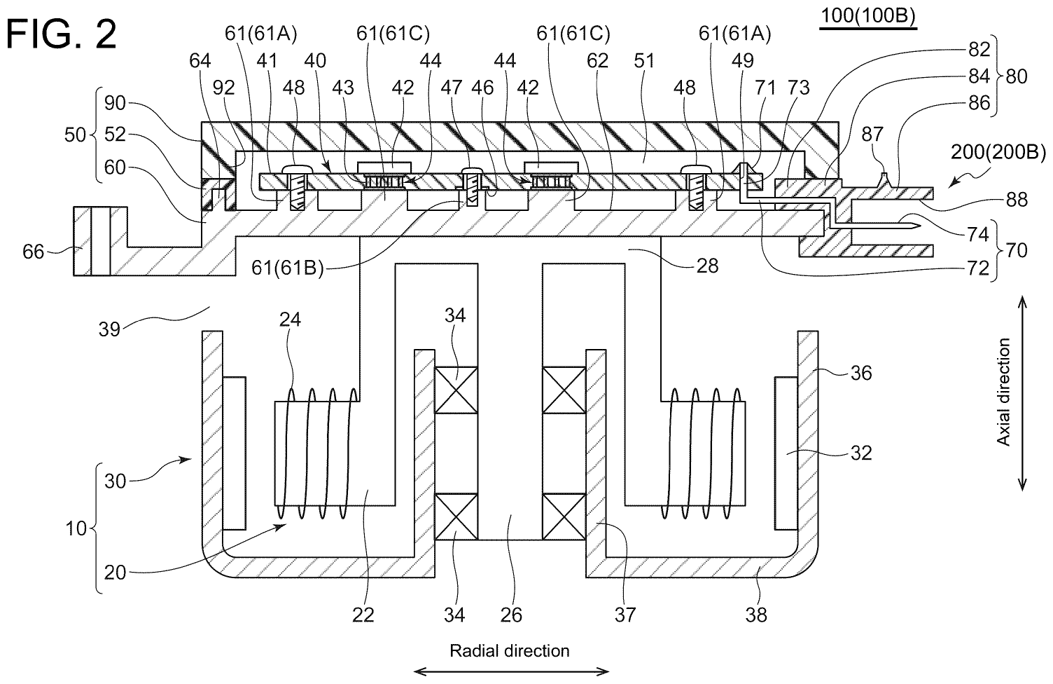

FIG. 1 is a cross-sectional view schematically showing a circuit-integrated motor 100A according to an embodiment. FIG. 2 is a cross-sectional view schematically showing a circuit-integrated motor 100B according to another embodiment.

The circuit-integrated motors 100A and 100B shown in FIGS. 1 and 2 are each a specific example of a circuit-integrated motor 100 according to some embodiments of the present invention.

In some embodiments, as shown in FIGS. 1 and 2, the circuit-integrated motor 100 (100A, 100B) includes a motor 10, a control board 40 for controlling the motor 10, and a casing 50 forming a board housing chamber 51 for housing the control board 40.

The motor 10 includes a stator 20 including a stator core 22, and a rotor 30 having a magnet 32 disposed so as to face the stator core 22 in the radial direction. The stator core 22 is wound with a stator coil 24. The stator coil 24 is electrically connected to the control board 40.

When a current flows through the stator coil 24 via the control board 40, the rotor 30 rotates in the circumferential direction due to interaction between the magnet 32 and a magnetic field created by the stator coil 24. Power supplied to the stator coil 24 is controlled by an inverter circuit included in the control board 40.

In the embodiments shown in FIGS. 1 and 2, the circuit-integrated motor 100 (100A, 100B) is an outer rotor motor in which the magnet 32 of the rotor 30 is located on an outer peripheral side of the stator core 22 of the stator 20.

Specifically, as shown in FIGS. 1 and 2, the stator 20 includes the stator core 22 on which the stator coil 24 is wound, a support shaft 26 rotatably supporting the rotor 30 via a bearing 34, and a base 28 attached to the casing 50. The base 28 is attached to a lower portion (a partition wall portion 60 described later) of the casing 50 with an unshown fastening member (such as a bolt). The stator core 22 and the support shaft 26 each extend in the axial direction from the base 28 toward an opposite side from the casing 50. The stator core 22 is located radially outward of the support shaft 26 so as to surround the support shaft 26. The magnet 32 of the rotor 30 is disposed on the outer peripheral side of the stator core 22. The rotor 30 has a double cylindrical structure including an outer peripheral wall 36 and an inner peripheral wall 37, and the outer peripheral wall 36 and the inner peripheral wall 37 are connected to each other via a bottom wall 38. The magnet 32 is attached to an inner peripheral surface of the outer peripheral wall 36. A vent 39 is formed between the rotor 30 and the casing 50 (the partition wall portion 60 described later). The vent 39 is formed by an axial clearance between the outer peripheral wall 36 of the rotor 30 and the casing 50 (the partition wall portion 60 described later).

In another embodiment, the circuit-integrated motor 100 is an inner rotor motor in which the rotor 30 is located on an inner peripheral side of the stator 20. The inner rotor circuit-integrated motor 100 has the same basic configuration as the examples shown in FIGS. 1 and 2, except for a positional relationship between the rotor 30 and the stator 20.

The control board 40 includes a printed wiring board 41, and a plurality of electronic devices 42 mounted on the printed wiring board 41.

Each of the electronic devices 42 may be a component of an inverter circuit for controlling power supplied to the stator coil 24 of the motor 10, and may be, for example, a semiconductor device represented by a FET. Alternatively, each of the electronic devices 42 may be a passive element such as a capacitor or a coil.

In some embodiments, as shown in FIGS. 1 and 2, the control board 40 includes heat-dissipating members 44 for thermally connecting the electronic devices 42 to the partition wall portion 60 serving as a heat sink. A heat via, a heat-conductive grease, a heat-conductive tape, etc. can be used as the heat-dissipating members 44.

In the exemplary embodiments shown in FIGS. 1 and 2, the heat-dissipating members 44 are disposed inside the control board 40 so as to form a heat transfer path from the electronic devices 42, which are mounted on a surface of the control board 40 opposite to the partition wall portion 60, to the partition wall portion 60 serving as the heat sink. In this case, the heat-dissipating members 44 may include a plurality of heat vias 43 penetrating the control board 40.

In another embodiment, the heat-dissipating members 44 are disposed between the electronic devices 42 and the partition wall portion 60 so as to form a heat transfer path from the electronic devices 42, which are mounted on a surface of the control board 40 facing the partition wall portion 60, to the partition wall portion 60 serving as the heat sink.

Further, the control board 40 may include a ground terminal 46 electrically connected to the partition wall portion 60.

In the embodiments shown in FIGS. 1 and 2, the ground terminal 46 disposed on the surface of the control board 40 facing the partition wall portion 60 is electrically connected to the partition wall portion 60 by screwing a screw 47 inserted into a through hole in the control board 40 into a female screw disposed in the partition wall portion 60 (a second protruding portion 61B described later).

The casing 50 includes the partition wall portion 60 made of metal and dividing the board housing chamber 51 for housing the control board 40 from a placement space for the motor 10.

A material forming the partition wall portion 60 is not particularly limited, but, for example, an aluminum alloy can be used.

The partition wall portion 60 includes a board facing surface 62 facing the control board 40 in the axial direction, and an outer peripheral edge 64 protuberantly disposed on a side opposite to the motor placement space (board housing chamber 51 side) so as to surround the board facing surface 62. The board facing surface 62 of the partition wall portion 60 forms a bottom surface of the board housing chamber 51.

The board facing surface 62 of the partition wall portion 60 may be provided with not less than one kind of protruding portions 61 for achieving a desired function.

In the embodiments shown in FIGS. 1 and 2, the protruding portions 61 include first protruding portions 61A with female screws into which screws 48 are screwed, the second protruding portion 61B with the female screw into which the screw 47 is screwed, and third protruding portions 61C in contact with the heat-dissipating members 44. The first protruding portions 61A are disposed on the board facing surface 62 in order to fix the control board 40 to the partition wall portion 60 by using the screws 48. The second protruding portion 61B is disposed on the board facing surface 62 in order to establish electrical connection between the ground terminal 46 of the control board 40 and the partition wall portion 60. The third protruding portions 61C are disposed on the board facing surface 62 in order to establish thermal connection between the electronic devices 42 and the partition wall portion 60.

A portion, of the board facing surface 62 of the partition wall portion 60, excluding the protruding portions 61, may be flat or may have a recessed portion. For example, if the electronic devices 42 are mounted on a surface of the control board 40 facing the board facing surface 62, the board facing surface 62 may have a recessed portion for avoiding interference with the electronic devices 42.

The outer peripheral edge 64 of the partition wall portion 60 may continuously be disposed over an entire circumference or may be formed with a notch in a partial circumferential range.

In the exemplary embodiment shown in FIG. 1, the outer peripheral edge 64 of the partition wall portion 60 is continuously disposed over the entire circumference including a circumferential position where a terminal 70 described later is disposed. By contrast, in the exemplary embodiment shown in FIG. 2, the outer peripheral edge 64 of the partition wall portion 60 has a partial notch in the circumferential position where the terminal 70 is disposed, and is discontinuous with respect to the circumferential direction at the position of the notch.

In some embodiments, as shown in FIGS. 1 and 2, the partition wall portion 60 has an attachment portion 66 overhung radially outward. The attachment portion 66 is used to install the circuit-integrated motor 100. For example, if the circuit-integrated motor 100 is an in-car motor, the circuit-integrated motor 100 may be attached to a vehicle body via the attachment portion 66.

In addition to the above configuration, the circuit-integrated motor 100 includes the terminal 70 for connecting the control board 40 to an external device, and a terminal holder (connector housing) 80 which is formed of resin and holds the terminal 70.

As shown in FIGS. 1 and 2, the terminal 70 is a metal component disposed to penetrate the casing 50, and has a first end portion 72 located inside the board housing chamber 51 and connected to the control board 40 and a second end portion 74 located outside the board housing chamber 51. The first end portion 72 of the terminal 70 is electrically connected to a circuit pattern of the control board 40 via solder 71, for example. The second end portion 74 of the terminal 70 is connected to the external device via a cable (not shown).

In the exemplary embodiments shown in FIGS. 1 and 2, a tip 73 of the first end portion 72 of the terminal 70 bends in a direction (axial direction) from the board facing surface 62 of the partition wall portion 60 toward the control board 40 and is inserted into a through hole 49 disposed in the control board 40. The tip 73 of the first end portion 72 inserted into the through hole 49 is connected to the circuit pattern of the control board 40 by the solder 71.

The terminal holder 80 is formed integrally with the partition wall portion 60 and the terminal 70, as shown in FIGS. 1 and 2.

Specifically, the terminal holder 80 formed of the resin is molded integrally with the partition wall portion 60 made of the metal, by insert molding with the partition wall portion 60 and the terminal 70 being insert parts. Herein, insert molding is a molding process in which an insert part is disposed in a mold prior to molding, resin is injected around the insert part, and the insert part and the resin are integrated. As the result of insert molding, an insert molded article 200 (200A, 200B) in which the partition wall portion 60 and the terminal 70 are partially embedded in the resin forming the terminal holder 80.

From the viewpoint of securing a joint strength between the partition wall portion 60 and the resin in the insert molded article 200 (200A, 200B), a joint surface of the partition wall portion 60 to the resin may be roughened by laser irradiation, roughening using chemicals, alumite treatment, etc.

In some embodiments, as shown in FIGS. 1 and 2, the terminal holder 80 includes a base portion 82 joined to the board facing surface 62 of the partition wall portion 60, an intermediate portion 84 located on an outer peripheral side of the base portion 82, and an extension portion 86 extending outward of the board housing chamber 51.

The base portion 82 of the terminal holder 80 is disposed on the board facing surface 62 so as to be at least partially located in the board housing chamber 51. The first end portion 72 of the terminal 70 protrudes from the base portion 82 of the terminal holder 80, and the tip 73 of the first end portion 72, which is bent toward the control board 40, is inserted into the through hole 49 in the control board 40.

The intermediate portion 84 of the terminal holder 80 is joined to the outer peripheral edge 64 of the partition wall portion 60.

Herein, in the example shown in FIG. 2, the outer peripheral edge 64 of the partition wall portion 60 has the partial notch at the circumferential position where the terminal 70 is disposed, and a junction between the intermediate portion 84 of the terminal holder 80 and the outer peripheral edge 64 of the partition wall portion 60 is not shown. However, also in the embodiment shown in FIG. 2, the intermediate portion 84 of the terminal holder 80 is joined to a portion of the outer peripheral edge 64 excluding the notch (a portion adjacent to the notch in the circumferential direction).

The extension portion 86 of the terminal holder 80 is disposed to extend radially outward from the intermediate portion 84 so as to be located on an opposite side of the intermediate portion 84 from the base portion 82 in the radial direction. The extension portion 86 of the terminal holder 80 has an engagement pawl 87 with which an end portion of a cable for connection to the external device can be engaged, and a recessed portion 88 where the second end portion 74 of the terminal 70 is exposed. The second end portion 74 of the terminal 70 extends radially outward along the extension portion 86 in the recessed portion 88.

In some embodiments, as shown in FIGS. 1 and 2, the terminal holder 80 is disposed integrally with a first resin portion 52 surrounding the board housing chamber 51. The first resin portion 52, as part of the casing 50, partially forms a peripheral wall of the board housing chamber 51.

When the terminal holder 80 is disposed integrally with the first resin portion 52, the insert molded article 200 has a structure in which the insert parts including the partition wall portion 60 and the terminal 70 are at least partially embedded in a resin portion including the first resin portion 52 and the terminal holder 80. In this case, the terminal holder 80 is the resin portion of the insert molded article 200, which is disposed seamlessly continuous with the first resin portion 52.

The casing 50 further includes a cover portion 90 for sealing the board housing chamber 51 after assembling the control board 40 to the partition wall portion 60. The cover portion 90 defines a boundary of the board housing chamber 51 together with the partition wall portion 60 and the first resin portion 52, and prevents a foreign matter (a water droplet, dust, etc.) from entering the board housing chamber 51 from outside.

In the embodiments shown in FIGS. 1 and 2, the cover portion 90 includes a second resin portion 92 welded to the first resin portion 52. The first resin portion 52 and the second resin portion 92 form the peripheral wall of the board housing chamber 51. The board housing chamber 51 is bounded in the radial direction by the first resin portion 52 and the second resin portion 92, and is bounded in the axial direction by the board facing surface 62 of the partition wall portion 60 and an inner surface of the cover portion 90.

The first resin portion 52 and the second resin portion 92 may be joined by, for example, laser welding, ultrasonic welding, or spin welding. If the spin welding is adopted, the peripheral wall of the board housing chamber 51, which is formed the first resin portion 52 and the second resin portion 92, desirably has a circular shape.

In the exemplary embodiments shown in FIGS. 1 and 2, the cover portion 90 is a resin cover formed entirely by a resin material. In another embodiment, the cover portion 90 includes a resin portion including the second resin portion 92, and a portion formed by a different material other than the resin material.

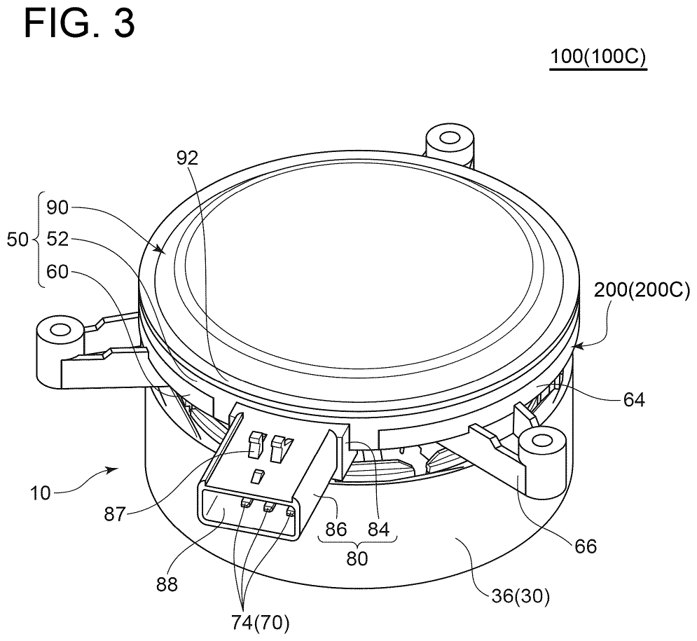

Subsequently, a detailed structure of the circuit-integrated motor 100 according to some embodiments will be described with reference to FIGS. 3 to 8.

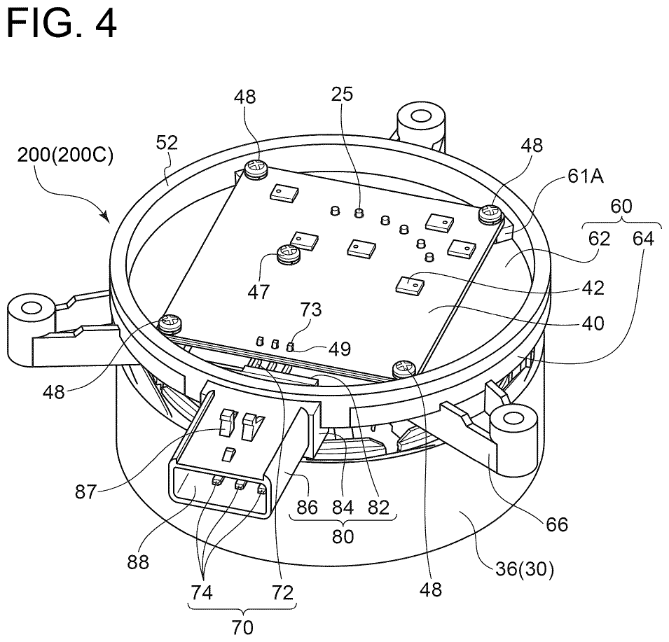

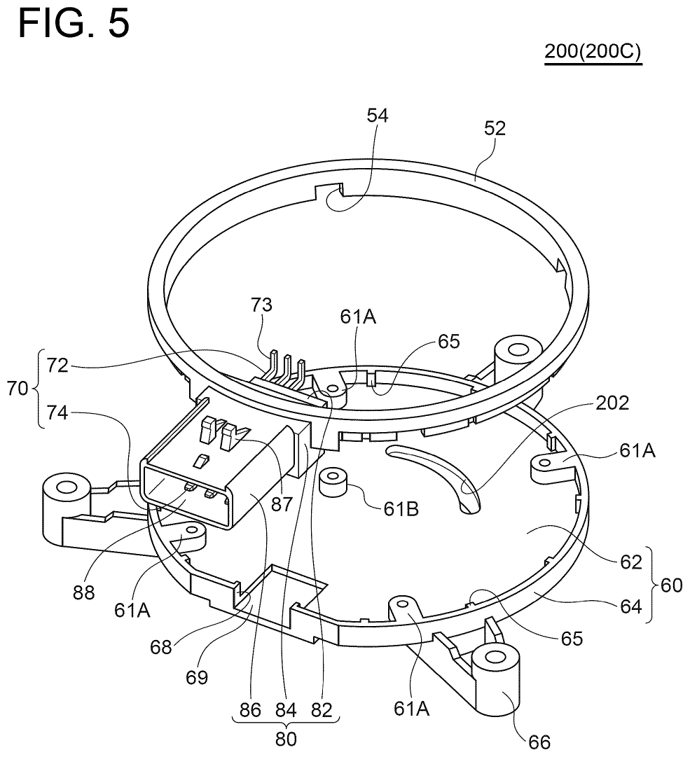

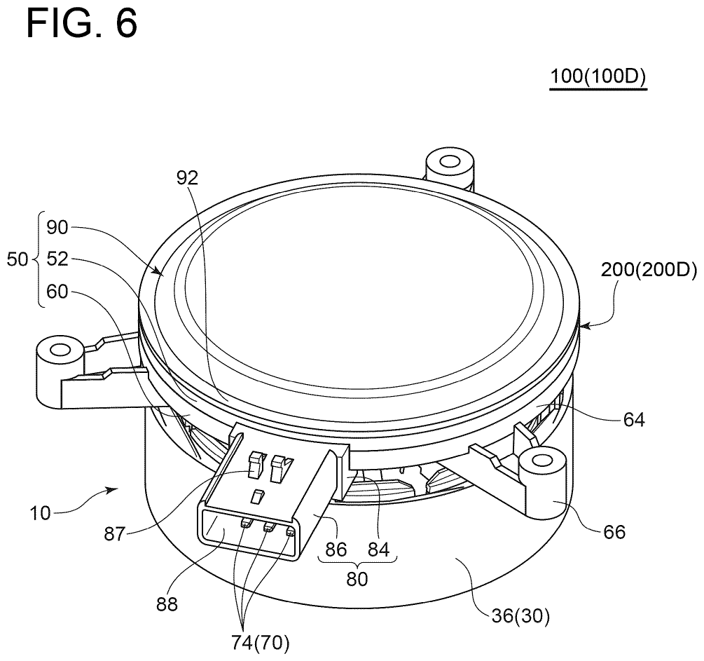

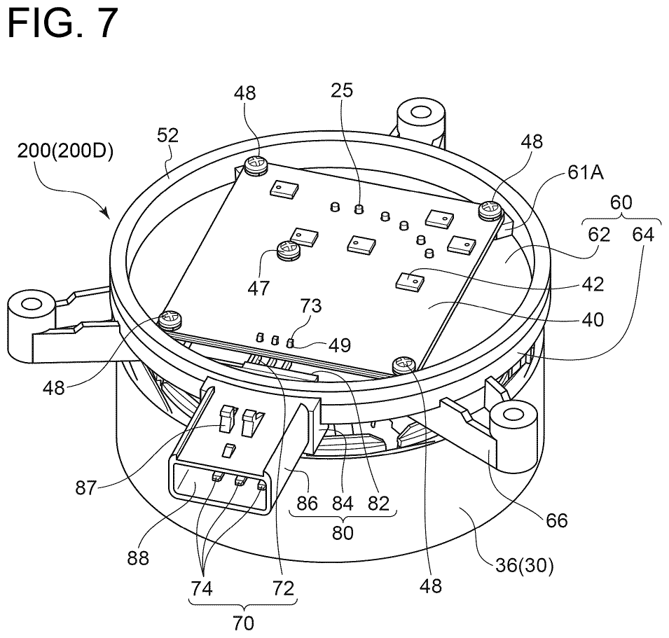

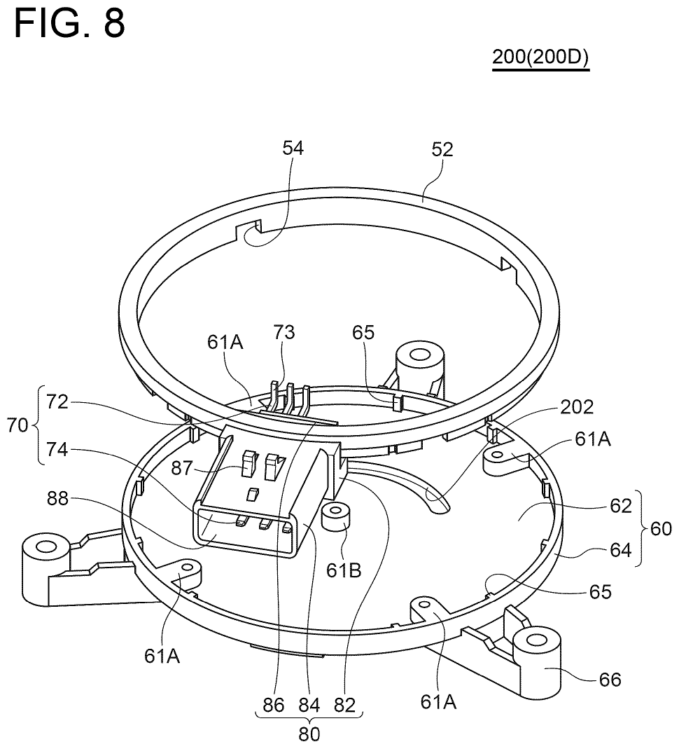

FIGS. 3 to 5 are each a perspective view showing a circuit-integrated motor 100C according to an embodiment. FIG. 3 shows an overall configuration of the circuit-integrated motor 100C, FIG. 4 shows a state of the circuit-integrated motor 100C before a cover is attached, and FIG. 5 illustrates, of the insert molded article 200C, the partition wall portion 60 separately from the other portions. FIGS. 6 to 8 are each a perspective view showing a circuit-integrated motor 100D according to another embodiment. FIG. 6 shows an overall configuration of the circuit-integrated motor 100D, FIG. 7 shows a state of the circuit-integrated motor 100D before the cover is attached, and FIG. 8 illustrates, of the insert molded article 200D, the partition wall portion 60 separately from the other portions.

Hereinafter, description of portions of the circuit-integrated motors 100C and 100D that are common to the configurations described above with reference to FIGS. 1 and 2 will be simplified or omitted.

In the circuit-integrated motors 100C and 100D, as shown in FIGS. 3 to 8, the terminal holder 80 and the first resin portion 52 are disposed integrally with the terminal 70 and the partition wall portion 60 made of the metal, by insert molding with the partition wall portion 60 and the terminal 70 being the insert parts. That is, in the circuit-integrated motors 100C and 100D, part of the casing 50 is formed by the insert molded article 200 (see FIGS. 5 and 8) where the partition wall portion 60 and the terminal 70 which are the insert parts made of the metal are partially embedded in the resin material including the terminal holder 80 and the first resin portion 52.

FIGS. 5 and 8 show, of the insert molded article 200, the partition wall portion 60 separately from the other portions. In reality, however, the partition wall portion 60 forms the insert molded article 200 integrally with the other portions, and the partition wall portion 60 cannot be separated from the other portions without destruction.

As shown in FIGS. 4 and 7, the control board 40 is assembled to the partition wall portion 60 of the insert molded article 200. Specifically, the control board 40 is assembled to the first protruding portions 61A of the partition wall portion 60 by screwing the screws 48 located at corners of the control board 40 into the female screws of the first protruding portions 61A of the partition wall portion 60.

The ground terminal (the ground terminal 46 in FIGS. 1 and 2) of the control board 40 is electrically connected to the partition wall portion 60 by screwing the screw 47 into the female screw of the second protruding portion 61B (see FIGS. 5 and 8) of the partition wall portion 60.

In the embodiments shown in FIGS. 4 and 7, the control board 40 is electrically connected to a motor wire 25 which is an end portion of the stator coil 24 of the motor 10, and the first end portion 72 of the terminal 70 of the insert molded article 200.

The motor wire 25 passes through an opening 202 (see FIGS. 5 and 8) disposed in the partition wall portion 60 of the insert molded article 200 and enters the board housing chamber 51 from the placement space for the motor 10, and a tip portion of the motor wire 25 is inserted into a through hole disposed in the control board 40. A gap around the motor wire 25 in the opening 202 is sealed with a rubber material in order to ensure sealability of the board housing chamber 51. The tip 73 of the first end portion 72 of the terminal 70 bends in the axial direction which is a direction from the board facing surface 62 of the partition wall portion 60 toward the control board 40, and is inserted into the through hole 49 disposed in the control board 40. A tip portion of the motor wire 25 protruding from the surface of the control board 40 and the tip 73 of the first end portion 72 of the terminal 70 are electrically connected to the circuit pattern of the control board 40 by soldering, for example.

The electronic devices 42 mounted on the control board 40 are thermally connected to the partition wall portion 60 of the insert molded article 200 via a heat-dissipating member (not shown).

As shown in FIGS. 4 and 7, the terminal holder (connector housing) 80 holding the terminal 70 and formed of the resin extends in the radial direction over the inside and outside of the board housing chamber 51, as part of the resin portion of the insert molded article 200.

The terminal holder 80 includes the base portion 82 located on the innermost side in the radial direction, the extension portion 86 located on the outermost side in the radial direction, and the intermediate portion 84 located between the base portion 82 and the extension portion 86. The base portion 82 is joined to the board facing surface 62 of the partition wall portion 60 in the board housing chamber 51. The terminal holder 80 is disposed integrally with the first resin portion 52 forming the peripheral wall of the board housing chamber 51 together with the second resin portion 92 of the cover portion 90. The first resin portion 52 is continuously disposed over the entire circumference. An upper end surface of the first resin portion 52 continuously disposed over the entire circumference is a joint surface with the second resin portion 92 of the cover portion 90 and is a flat surface along a plane orthogonal to the axial direction. Further, as shown in FIGS. 4, 5, 7, and 8, the upper end surface of the first resin portion 52 is circumferential around a rotational axis of the rotor 30 of the motor 10. Therefore, the first resin portion 52 and the second resin portion 92 can be joined by spin welding.

In some embodiments, as shown in FIGS. 5 and 8, the partition wall portion 60 of the insert molded article 200 has uneveness in the joint surface with the resin from the viewpoint of improving the strength of the insert molded article 200.

Specifically, the first protruding portions 61A protrude radially inwardly from the outer peripheral edge 64 of the partition wall portion 60, and in the first resin portion 52 of the insert molded article 200, recessed portions 54 are formed at circumferential positions corresponding to the first protruding portions 61A. Further, a plurality of longitudinal ribs 65 are formed on an inner peripheral surface of the outer peripheral edge 64 of the partition wall portion 60, and recessed portions corresponding to the longitudinal ribs 65 are formed in the first resin portion 52 of the insert molded article 200. The plurality of longitudinal ribs 65 each extend along the axial direction on the inner peripheral surface of the outer peripheral edge 64.

Furthermore, in the embodiment shown in FIG. 5, the partition wall portion 60 has a notch 68 disposed in the outer peripheral edge 64 for the terminal 70 to pass through, and a recess 69 disposed in the board facing surface 62 so as to connect to the notch 68. Therefore, the base portion 82 and the intermediate portion 84 of the terminal holder 80 of the insert molded article 200C have complementary shapes with respect to the notch 68 and the recess 69 of the partition wall portion 60.

The insert molded article 200D shown in FIG. 8 contrasts with the insert molded article 200C, where the outer peripheral edge 64 of the partition wall portion 60 has the notch 68, in that the outer peripheral edge 64 is continuously disposed over the entire circumference including the circumferential position at which the terminal 70 is disposed.

In the insert molded article 200D, the terminal 70 is embedded inside the terminal holder 80 so as to ride over the outer peripheral edge 64, as with the embodiment shown in FIG. 1.

The characteristic configurations of the circuit-integrated motor according to some embodiments described above are summarized as follows.

[1] A circuit-integrated motor (100) according to some embodiments, includes: a motor (10); a control board (40) for controlling the motor (10); a casing (50) including a partition wall portion (60) made of metal and dividing a board housing chamber (51) for housing the control board (40) from a placement space for the motor (10); a terminal (70) for connecting the control board (40) to an external device; and a terminal holder (80) formed of resin and holding the terminal (70). The terminal holder (80) is molded integrally with the partition wall portion (60) by insert molding with the partition wall portion (60) and the terminal (70) being insert parts.

According to the above configuration [1], since the terminal holder (80) is disposed integrally with the terminal (70) and the partition wall portion (60) for dividing the board housing chamber (51) from the motor placement space, the number of parts and part assembly man-hours can be reduced compared to a case where a connector including the terminal and the terminal holder formed of the resin is fastened to the partition wall portion.

[2] In some embodiments, in the above configuration [1], the partition wall portion (60) includes: a board facing surface (62) facing the control board (40); and an outer peripheral edge (64) protuberantly disposed on a side of the board housing chamber (51) so as to surround the board facing surface (62), and the terminal holder (80) includes: a base portion (82) joined to the board facing surface (62) of the partition wall portion (60); an intermediate portion (84) joined to the outer peripheral edge (64) of the partition wall portion (60); and an extension portion (86) extending outward of the board housing chamber (51) so as to be located on an opposite side of the intermediate portion (84) from the base portion (82).

According to the above configuration [2], a joint strength between the terminal holder and the partition wall portion can be improved by performing insert molding such that the terminal holder (80) is joined to, of the partition wall portion (60), the board facing surface (62) and the outer peripheral edge (64) which is a protuberant portion.

[3] In some embodiments, in the above configuration [2], the terminal holder (70) includes: a first end portion (72) protruding from the base portion (82) and connected to the control board (40); and a second end portion (74) extending radially outward along the extension portion (86) so as to protrude from the terminal holder (80), and a tip (73) of the first end portion (72) of the terminal (70) bends in a direction from the board facing surface (62) toward the control board (40) and is inserted into a through hole (49) disposed in the control board (40).

According to the above configuration [3], since the tip (73) of the first end portion (72) of the terminal (70) protruding from the base portion (82) bends in the direction from the board facing surface (62) toward the control board (40), the control board (40) and the terminal (70) can easily be connected by inserting the tip (73) of the first end portion (72) of the terminal (70) into the through hole (49) of the control board (40), when the control board (40) is assembled to the partition wall portion (60).

[4] In some embodiments, in the above configuration [2] or [3], the outer peripheral edge (64) of the partition wall portion (60) includes a notch (68) through which a portion of the terminal (70) embedded in the terminal holder (80) passes, and the intermediate portion (84) of the terminal holder (80) is disposed integrally with the outer peripheral edge (64) of the partition wall portion (60) so as to fill the notch (68) of the partition wall portion (60).

According to the above configuration [4], the degree of freedom of layout of the terminal (70) is improved, making it possible to simplify the shape of the terminal (70).

[5] In some embodiments, in the above configuration [2] or [3], a portion of the terminal (70) embedded in the terminal holder (80) is disposed inside the intermediate portion (84) of the terminal holder (80) so as to ride over the outer peripheral edge (64) of the partition wall portion (60).

According to the above configuration [5], the outer peripheral edge (64) of the partition wall portion (60) can continuously be disposed in the vicinity of the terminal (70) by adopting layout of the terminal (70), which avoids the outer peripheral edge (64) of the partition wall portion (60). Therefore, a joint area between the terminal holder (80) formed of the resin and the partition wall portion (60) can be secured easily compared to a case where the notch (68) is disposed in the outer peripheral edge (64) of the partition wall portion (60).

[6] In some embodiments, in any of the above configurations [1] to [5], an electronic device (42) of the control board (40) is thermally connected via a heat-dissipating member (44) to the partition wall portion (60) serving as a heat sink.

According to the above configuration [6], the circuit-integrated motor (100) with excellent reliability can be realized with a small number of parts by causing the partition wall portion (60) made of the metal and configured to divide the board housing chamber (51) from the motor placement space to function as the heat sink.

[7] In some embodiments, in any of the above configurations [1] to [6], a ground terminal (46) of the control board (40) is electrically connected to the partition wall portion (60).

According to the above configuration [7], a reference potential of the control board (40) can be stabilized by using as a ground the partition wall portion (60) made of the metal and configured to divide the board housing chamber (51) from the motor placement space. Whereby, the circuit-integrated motor (100) with excellent reliability can be realized with a small number of parts.

[8] In some embodiments, in any of the above configurations [1] to [7], the partition wall portion (60) is made of an aluminum alloy.

According to the above configuration [8], the weight of the circuit-integrated motor (100) can be reduced by using the partition wall portion (60) made of the lightweight aluminum alloy.

Further, since the aluminum alloy has excellent thermal conductivity and electrical conductivity, the aluminum alloy is suitable as a material for the partition wall portion (60) when the partition wall portion (60) is to function as the heat sink or the ground as in the above [6] or [7].

[9] In some embodiments, in any of the above configurations [1] to [8], the motor (10) includes: a stator (20) attached to the partition wall portion (60) so as to be located on an opposite side of the partition wall portion (60) from the board housing chamber (51), and including a stator core (22); a stator coil (24) wound around the stator core (22); and a rotor (30) including a magnet (32) disposed on an outer peripheral side of the stator core (22) so as to face the stator core (22) in a radial direction, and a vent (39) is formed between the rotor (30) and the partition wall portion (60).

According to the above configuration [9], by adopting an outer rotor motor in which the magnet (32) of the rotor (30) is located on the outer peripheral side of the stator core (22), unlike in the case of an inner rotor motor, a cylindrical motor housing for holding the stator on the outer peripheral side of the rotor is unnecessary. Therefore, it is not necessary to provide a connection with the cylindrical motor housing in an outer peripheral region of the partition wall portion (60), making it possible to simplify the shape of the partition wall portion (60) and to reduce a production cost of the mold for insert molding in the above [1].

Further, by adopting the outer rotor motor, the cylindrical motor housing required for the inner rotor motor can be omitted and the vent (39) can be formed between the rotor (30) and the partition wall portion (60). Whereby, heat generated in the control board (40) and the motor (10) which are located on both sides of the partition wall portion (60) can effectively be discharged by airflow via the vent (39).

Some embodiments of the invention have been described above, and as a matter of course, the above embodiments may be modified as long as they do not depart from the spirit of the present invention.

For example, FIGS. 1 to 8 show the structure in which the insert molded article including the partition wall portion 60, the terminal 70, the terminal holder 80, and the first resin portion 52 is joined to the cover portion 90 by welding first resin portion 52 and the second resin portion 92. However, the present invention is not limited to this example. For example, the casing 50 defining the boundary of the board housing chamber 51 may be formed by fastening the insert molded article including the partition wall portion 60, the terminal 70, and the terminal holder 80 to the cover portion 90. In this case, a seal member may be disposed between and the cover portion 90 and the outer peripheral edge 64 of the partition wall portion 60 to ensure the sealability of the board housing chamber 51.

Further, in the present specification, the expressions “comprising”, “including” or “having” one constitutional element is not an exclusive expression that excludes the presence of other constitutional elements.

1. A circuit-integrated motor, comprising:
a motor;
a control board for controlling the motor;
a casing including a partition wall portion made of metal and dividing a board housing chamber for housing the control board from a placement space for the motor;
a terminal for connecting the control board to an external device; and
a terminal holder formed of resin and holding the terminal,
the terminal holder being molded integrally with the partition wall portion by insert molding with the partition wall portion and the terminal being insert parts.

2. The circuit-integrated motor according to claim 1, wherein
the partition wall portion includes:
a board facing surface facing the control board; and
an outer peripheral edge protuberantly disposed on a side of the board housing chamber so as to surround the board facing surface, and
the terminal holder includes:
a base portion joined to the board facing surface of the partition wall portion;
an intermediate portion joined to the outer peripheral edge of the partition wall portion; and
an extension portion extending outward of the board housing chamber so as to be located on an opposite side of the intermediate portion from the base portion.

3. The circuit-integrated motor according to claim 2, wherein
the terminal includes:
a first end portion protruding from the base portion and connected to the control board; and
a second end portion extending radially outward along the extension portion so as to protrude from the terminal holder, and
a tip of the first end portion of the terminal bends in a direction from the board facing surface toward the control board and is inserted into a through hole disposed in the control board.

4. The circuit-integrated motor according to claim 2, wherein
the outer peripheral edge of the partition wall portion includes a notch through which a portion of the terminal embedded in the terminal holder passes, and
the intermediate portion of the terminal holder is disposed integrally with the outer peripheral edge of the partition wall portion so as to fill the notch of the partition wall portion.

5. The circuit-integrated motor according to claim 2, wherein
a portion of the terminal embedded in the terminal holder is disposed inside the intermediate portion of the terminal holder so as to ride over the outer peripheral edge of the partition wall portion.

6. The circuit-integrated motor according to claim 1, wherein
an electronic device of the control board is thermally connected via a heat-dissipating member to the partition wall portion serving as a heat sink.

7. The circuit-integrated motor according to claim 1, wherein
a ground terminal of the control board is electrically connected to the partition wall portion.

8. The circuit-integrated motor according to claim 1, wherein
the partition wall portion is made of an aluminum alloy.

9. The circuit-integrated motor according to claim 1, wherein
the motor includes:
a stator attached to the partition wall portion so as to be located on an opposite side of the partition wall portion from the board housing chamber, and including a stator core;
a stator coil wound around the stator core; and
a rotor including a magnet disposed on an outer peripheral side of the stator core so as to face the stator core in a radial direction, and
a vent is formed between the rotor and the partition wall portion.
